(19) United States
(12) Patent Application Publication
(10) Pub. No.: US 2025/0311205 A1
(43) Pub. Date: Oct. 2, 2025

(54) SEMICONDUCTOR STRUCTURE AND METHOD OF FORMING THE SAME

(71) Applicant: Fujian Jinhua Integrated Circuit Co., Ltd., Quanzhou City (CN)

(72) Inventors: Yingxiong Guo, Quanzhou City (CN); Wenzhang Li, Quanzhou City (CN); Bogeng Guo, Quanzhou City (CN)

(73) Assignee: Fujian Jinhua Integrated Circuit Co., Ltd., Quanzhou City (CN)

(21) Appl. No.: 18/889,395

(22) Filed: Sep. 19, 2024

(30) Foreign Application Priority Data
Apr. 2, 2024 (CN) 202410396139.6

(51) Int. Cl. H10B 12/00

(52) U.S. Cl. CPC H10B 12/50; H10B 12/09

(57) ABSTRACT

The present invention discloses semiconductor structure and its forming method comprising a pad array, comprising multiple pads spaced apart from each other along a first direction and a second direction, and disposed in multiple rows along the first direction; a pad boundary disposed outside all of the pads and comprising multiple first branches extending along the first direction; multiple second branches extending along the first direction and alternately disposed with the first branches along the third direction; and at least one first peripheral pad, positioned between the first branch and the pad along the first direction, and between the two adjacent two of the second branches along the third direction, wherein a gravity center of the at least one first periphery pad is not on a same straight line with a gravity centers of the pads arranged in the a same row along the first direction.

### BACKGROUND OF THE INVENTION

### 1. Field of the Invention

The present invention relates to a semiconductor structure and a method of forming the same, especially relates to a semiconductor structure including pads, and a method of forming the same.

### 2. Description of the Prior Art

Due to the miniaturization trend in electronics, the design of dynamic random access memory (DRAM) cells must be able to achieve high integration d high density. For DRAM cells with a recessed-gate structure, they can achieve longer carrier channel length within the same semiconductor substrate, which reduces the leakage in the capacitor structure. Consequently, under the current mainstream development trend, they have gradually replaced DRAM cells with only planar gate structures. Generally, DRAM cells with a recessed gate structure include a transistor component and a charge storage device, which receive voltage signals from a bit line and word line. However, due to limitations in process technology, existing DRAM cells with recessed gate structures still exhibit many drawbacks and thus require further improvement to effectively enhance the performance and reliability of related memory devices.

### SUMMARY OF THE INVENTION

An object of the present invention is to provide a semiconductor structure and a method for forming the same, in which peripheral pads with shifted gravity centers are arranged on at least one side of a pad array, so as to improve possible structural defects of the semiconductor structure caused by continuously increased cell density.

To achieve the above object, according to one embodiment of the present invention, a semiconductor structure including a pad array is provided. The pad array includes multiple pads, a pad boundary, multiple second branches, and at least one peripheral pad. The pads are disposed spaced apart from each other along a first direction and a second direction, and are arranged in multiple rows along the first direction. The pad boundary is disposed outside all of the pads and includes multiple first branches extending along the first direction. The second branches extend along the first direction and are alternatively arranged with the first branches along a third direction. At least one first peripheral pad is located between the first branch and the pad along the first direction, and is located between adjacent two of the second branches along the third direction, wherein a gravity center of the at least one peripheral pad is not on a same straight line with gravity centers of the pads arranged in a same row along the first direction.

To achieve the above object, according to another one embodiment of the present invention, a semiconductor structure including a pad array is provided. The pad array includes multiple pads, a pad boundary, and multiple second branches. The pads are disposed spaced apart from each other along a first direction and a second direction, and each pad has two opposite lateral sides parallel to each other along the first direction. The pad boundary is disposed around all of the pads and includes multiple first branches extending along the first direction. The second branches extend along the first direction and are alternatively arranged with the first branches in a third direction. At least one peripheral pad is located between the pad boundary and the pad along the first direction, and the at least one peripheral pads has two opposite lateral sides parallel to each other, and the two opposite lateral sides of the at least one peripheral pad are not parallel to the two opposite lateral sides of any of the pads.

To achieve the above object, according to the other embodiment of the present invention, a method of manufacturing another semiconductor structure is provided, which includes: providing a chip and forming a plugs array including multiple plugs; defining multiple first parallel patterns on the chip extending in a first direction; defining multiple second parallel patterns on the chip extending in a second direction which is different from the first direction; modifying an end of the at least one second patterns to define at least one modified pattern which has an end deviated from the first direction; and performing a first patterning process through the first parallel patterns, and performing a second patterning process through the modified patterns and the second parallel patterns to form a pad array on the plugs including multiple pads and at least one peripheral pad overlapping the underlying plugs respectively.

Overall, the semiconductor structure and the forming method thereof involve a modification step performed before carrying out two self-aligned reverse patterning processes, and the modification step adjusts the angle and/or line width of the end of the at least one pattern. This modification step ensures that the ends of the corresponding mask pattern highly align with the underlying plugs, so that the gravity centers of the peripheral pads that are subsequently formed on at least one side of the pad array offset from the gravity centers of the adjacent pads, or the lateral sides of the peripheral pads are not parallel to the lateral sides of the adjacent pads, thus ensuring the overlap ratio of the peripheral pads and the corresponding plugs. Therefore, structural defects in the semiconductor structure that are raised due to the continuously increased cell density can be mitigated.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying figures provide a more in-depth understanding of this embodiment and are incorporated herein by reference. These figures and descriptions serve to elucidate the principles of certain embodiments. It should be noted that all figures are schematic and are intended for the purpose of explanation and clarity in drawing. The relative dimensions and proportions have been adjusted accordingly. Identical reference numerals in different embodiments represent corresponding or similar features.

FIG. 1 and FIG. 2 are schematic views of the semiconductor structure according to a first embodiment of the present invention, wherein

FIG. 1 is a schematic top view of the semiconductor structure, and

FIG. 2 is a schematic cross-sectional view along section line D-D′ in FIG. 1.

FIG. 3 and FIG. 4 are schematic views of the semiconductor structure according to a second embodiment of the present invention, wherein

FIG. 3 is a schematic top view of the semiconductor structure, and

FIG. 4 is a schematic cross-sectional view along section line D-D′ in FIG. 3.

FIGS. 5-10 are schematic views of the method for forming the semiconductor structure according to a preferred embodiment of the present invention, wherein

FIG. 5 is a flow chart schematic view of the steps involved in the method for forming the semiconductor structure;

FIG. 6 is a schematic view of the semiconductor structure after forming parallel patterns;

FIG. 7 is a schematic view of the semiconductor structure after modifying the parallel patterns;

FIG. 8 is a schematic top view of the mask pattern formed according to the parallel patterns;

FIG. 9 is a schematic top view of the mask pattern formed according to the modified patterns; and

FIG. 10 is another schematic view of the structure after modifying the parallel patterns.

### DETAILED DESCRIPTION

To further facilitate the understanding of the present invention by those skilled in the art, the following preferred embodiments are described in detail with reference to the accompanying drawings. It should be understood that the following embodiments can be combined, replaced, and reorganized by combining features from different embodiments without departing from the spirit of the invention.

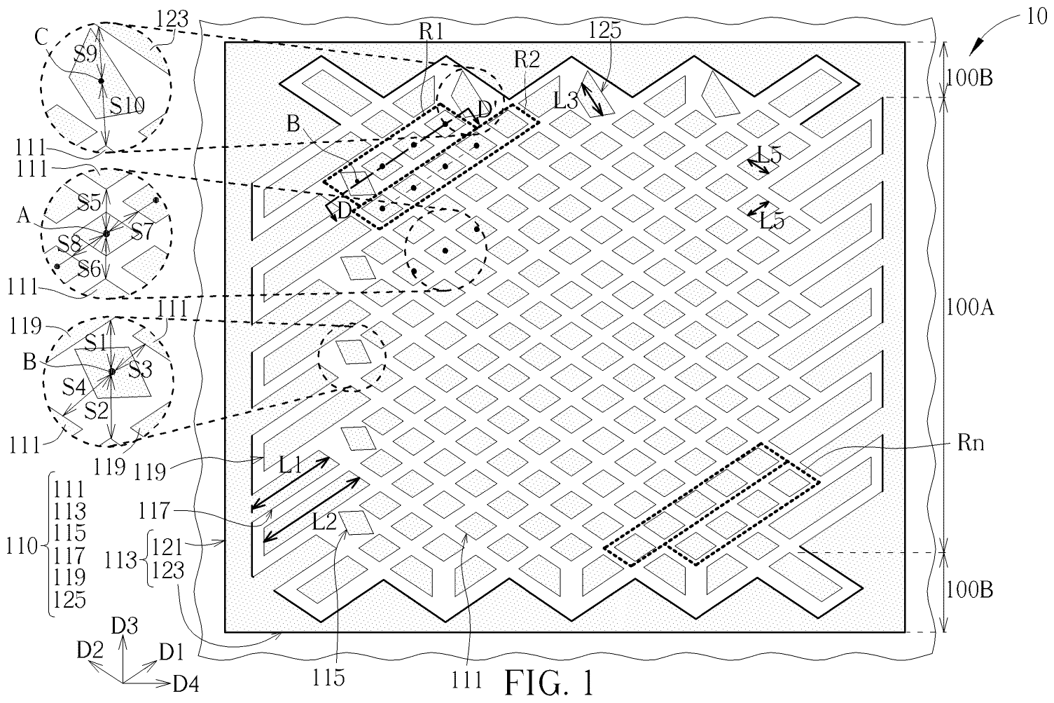

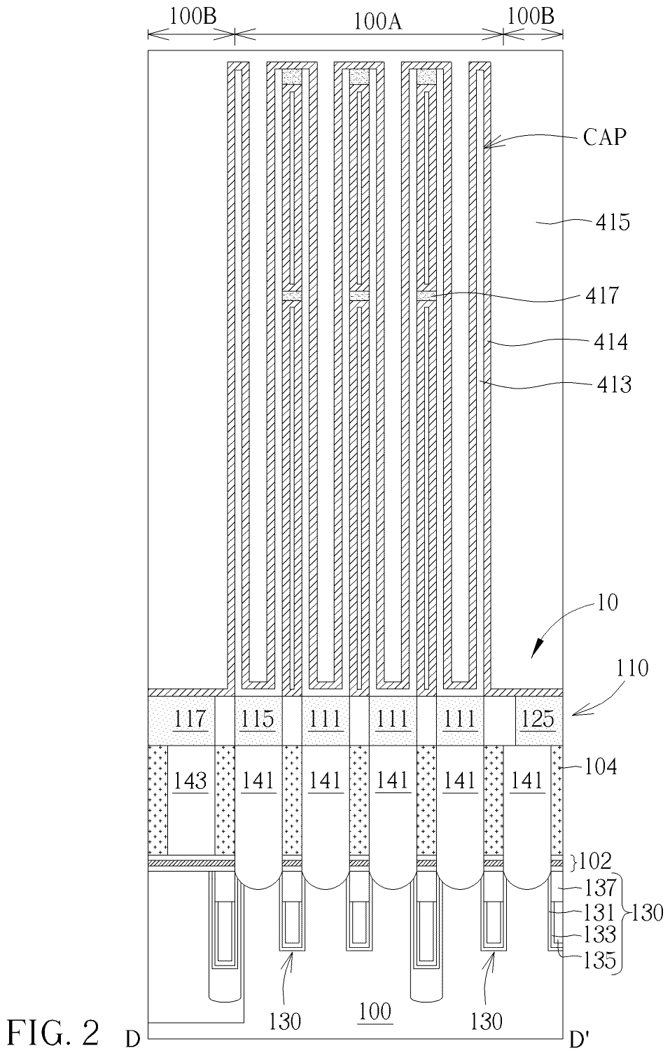

Refer to FIGS. 1 and 2, which are schematic diagrams of the semiconductor structure 10 in a first embodiment of the present invention. First, as shown in FIG. 1, the semiconductor structure 10 includes a pad array 110 which further includes a plurality of pads 111, a pad boundary 113, a first peripheral pad 115, a plurality of first branches 117, and a plurality of second branches 119. The pads 111 are spaced apart from each other and arranged along a first direction D1 and a second direction D2 which are interlaced to and not perpendicular to each other. The pads 111 are arranged in multiple rows R1, R2 . . . Rn along the first direction D1, to serve as storage node pads (SN pads) for a semiconductor device (not shown in the drawings, such as a dynamic random access memory device). The pad boundary 113 is located outside all of the pads 111, and the pad boundary 113 further includes the first branches 117 extending along the first direction D1. The second branches 119 also extend along the first direction D1 and are arranged alternately with the first branches 117 along a third direction D3. It should be noted that at least one first peripheral pad 115 is positioned between the first branch 117 and one of the pads 111 along the first direction D1, and between two adjacent second branches 119 along the third direction D3. While the gravity centers “A” of the pads 111 arranged in the same row R1, R2 . . . Rn all fall on the same extension line parallel to the first direction D1, the gravity center “B” of the at least one first peripheral pad 115 does not fall on the same extension line with the gravity centers “A” of the pads in a corresponding row. Under this arrangement, as shown in FIG. 2, the gravity centers “A”/“B” of the pads 111 and/or the at least one first peripheral pad 115 can correspond respectively to the gravity centers of the plugs 141 disposed underneath, ensuring the contact area between the pads 111 and/or the at least one first peripheral pad 115, and the corresponding plugs 141. Therefore, by disposing the first peripheral pad 115 on one side of the pad array 110, with the gravity center “B” of the first peripheral pad being deviated from the gravity centers “A” of pads 111 arranged in an adjacent row, the possible structural defects that may arise in the semiconductor structure 10 due to the continuously increased memory cell density will be improved thereby.

In detail, as shown in FIG. 1, the first branches 117 are sequentially arranged along the third direction D3, and a plurality of the first peripheral pads 115 are respectively located between each first branch 117 and a corresponding one of the pads 111, so that the first peripheral pads 115 are all located on one side of the pad array 110 and each has the gravity center “B” that deviate from the corresponding extension line. The gravity center “B” of each first peripheral pad 115 has a first distance S1 and a second distance S2 with respect to two adjacent ones of the second branches 119 in the third direction D3, respectively, and the first distance S1 is, for example, less than the second distance S2. Furthermore, the gravity center “B” of each first peripheral pad 115 has a third distance S3 and a fourth distance S4 with respect to one adjacent pad 111 and one adjacent first branch 117 in the first direction D1, respectively, and the third distance S3 is, for example, less than the fourth distance S4. On the other hand, the gravity center “A” of each pad 111 has a fifth distance S5 and a sixth distance S6 with respect to two adjacent ones of the pads 111 in the third direction D3, respectively, and a difference between the fifth distance S5 and the sixth distance S6 is, for example, less than a difference between the first distance S1 and the second distance S2. Similarly, the gravity center “A” of each pad 111 has a seventh distance S7 and an eighth distance S8 with respect to two adjacent ones of the pads 111 in the first direction D1, respectively, and a difference between the seventh distance S7 and the eighth distance S8 is, for example, less than a difference between the third distance S3 and the fourth distance S4. In a preferred embodiment, the fifth distance S5 and the sixth distance S6 are the same, and/or the seventh distance S7 and the eighth distance S8 are preferably the same; i.e., the difference between them is zero, but is not limited thereto.

As shown in FIG. 1, the pad boundary 113 includes two first edges 121 located along the third direction D3 and two second edges 123 located along the fourth direction D4 perpendicular to the third direction D3. In one embodiment, one end of each first edge 121 is directly connected to one end of each second edge 123, such that, the pad boundary 113 will form a rectangular frame structure as a whole that surrounds the pads 111 and the first peripheral pads 115, thereby achieving protection effect for the pads 111 and the first peripheral pads 115, but is not limited thereto. Those skilled in the art should readily understand that in another embodiment, the pad boundary may optionally include other edges to form other suitable shapes as a whole, thereby achieving a more optimized protection effect. Specifically, each first branch 117 is located on the first edge 121 and has a first length L1 along the first direction D1. Each second branch 119 is located close to but not in contact with the first edge 121 and has a second length L2 along the first direction D1. The first length L1 is less than the second length L2, but is not limited thereto.

The pad array 110 further includes a plurality of second peripheral pads 125, located between one of the second edges 123 of the pad boundary 113 and corresponding ones of the pads 111 in the third direction D3. It should be noted that the gravity center “C” of each second peripheral pad 125 also deviates from the extension line where the gravity centers A of the pads 111 arranged in a corresponding row. The gravity center “C” of each second peripheral pad 125 has a ninth distance S9 and a tenth distance S10 with respect to the adjacent second edge 123 and one corresponding pad 111 in the third direction D3, respectively. The ninth distance S9 is, for example, less than the tenth distance S10, and the ninth distance S9 is not equal to the aforementioned first distance S1, but is not limited thereto. In this way, the gravity centers “C” of the second peripheral pads 125 can also correspond to the gravity centers of the plugs 141 disposed underneath, as shown in FIG. 2, ensuring the contact area between the second peripheral pads 125 and the corresponding plugs 141. In one embodiment, a maximum extension length L3 of each second peripheral pad 125 is, for example, different from a maximum extension length L4 of each first peripheral pad 115. The maximum extension length L4 of the first peripheral pad 115 is preferably equal to a length L5 of each pad 111 along the first direction D1 or the second direction D2. Those skilled in the art should readily understand that the aforementioned first length L1, second length L2, maximum extension lengths L3, L4, and length L5 are all referred to an average length or a maximum length of each component of the pad array 110 in the first direction D1 or in the second direction D2, but are not limited thereto. The pad array 110 includes a low-resistance metal material, such as aluminum (Al), titanium (Ti), copper (Cu), or tungsten (W), preferably tungsten, but is not limited thereto.

As shown in FIGS. 1 and 2, the semiconductor structure 10 also includes a substrate 100 and a plurality of word lines 130 located within the substrate 100. The aforementioned pad array 110 is located on the substrate 100 for example, a silicon substrate, a silicon-containing substrate (e.g., sic, SiGe), a silicon-on-insulator substrate, or a substrate made of other suitable materials, but is not limited thereto. The pads 111 of the pad array 110 are generally located in a cell region 100A on the substrate 100, with the cell region 100A having a relative higher elemental integration, while the first branches 117, the second branches 119, and the like arranged at the periphery of the pad array 110 are generally located in a peripheral region 100B of the substrate 100, with the peripheral region 100B having a relative lower elemental integration. In one embodiment, the peripheral region 100B is located on at least one side of the cell region 100A. Preferably, from the top view shown in FIG. 1, the peripheral region 100B is disposed around the outer side of the cell region 100A, but is not limited thereto. The word lines 130 are spaced apart from each other and disposed within the substrate 100, and each word line 130 includes a dielectric layer 131, a gate dielectric layer 133, and a gate electrode 135 stacked in sequence, and a capping layer 137 covering the gate electrode 135, as shown in FIG. 2. The surface of the capping layer 137 may be aligned with the top surface of the substrate 100, so that each word line 130 serves as a buried word line (BWL) of the semiconductor device. The word lines 130 are isolated from the components located on the substrate 100 by an insulation layer 102 located on the substrate 100. In one embodiment, the insulation layer 102 preferably a an has multilayer structure, such as oxide-nitride-oxide (ONO) structure, but is not limited thereto.

As shown in FIG. 2, the semiconductor structure 10 also includes a plug array 140 located on the substrate 100, including a plurality of plugs 141, 143 located in the cell region 100A and the peripheral region 100B respectively. Each plug 141, 143 is alternately arranged with a plurality of isolation structures 104 along the first direction D1 for electrically insulating the adjacent plugs 141, 143 by the isolation structures 104. In one embodiment, the plugs 141, 143 for example include an epitaxial materials, such as silicon (Si), silicon phosphide (SiP), silicon germanium (SiGe), or germanium (Ge), or low-resistance metal materials, such as aluminum, titanium, copper, or tungsten, but are not limited thereto. Along the direction perpendicular to the substrate 100, each plug 141 is disposed below a corresponding one of the pads 111 or a corresponding one of the first peripheral pads 115 and in physical contact with the corresponding one of the pads 111 or the first peripheral pads 115. In this way, the top of each plug 141 will be electrically connected to the corresponding one of the pads 111 or the first peripheral pads 115, while the bottom portions of each plug 141 extend into the substrate 100 and is electrically connected to a transistor device (not shown in the drawing) located in the substrate 100, with each plug 141 serving as a storage node contact (SNC) of the semiconductor device thereby. The storage node contact may be further electrically connected to a storage node (SN) which is subsequently disposed on the pad array 110. On the other hand, each plug 143 is disposed below a corresponding one of the first branches 117 or a corresponding one of the second branches 119, and is in physical contact with the corresponding one of the first branches 117 or the second branches 119. However, the bottom of each plug 143 is located on the insulation layer 102 and is not in contact with substrate 100, serving as a dummy plug of the semiconductor device thereby.

According to the semiconductor structure 10 of the first embodiment of the present invention, by disposing the first peripheral pads 115 and/or the second peripheral pads 125 at the periphery of the pad array 110, for example on at least one side of the pad array 110, with the first peripheral pads 115 and/or the second peripheral pads 125 having the gravity centers deviating from the gravity centers “A” of the pads 111 arranged in an adjacent row such that, the gravity centers B/C of the first peripheral pads 115 and/or the second peripheral pads 125 adjacent to the pad boundary 113 can be able to correspond to the gravity centers of the plugs 141 underneath, ensuring the contact area between the first peripheral pads 115 and/or the second peripheral pads 125 and the corresponding plugs 141. Therefore, by disposing the first peripheral pads 115 and/or the second peripheral pads 125 with deviated gravity centers on at least one side of the pad array 110, the structural defects that may arise due to the continuously increased cell density in the semiconductor structure 10 can be mitigated. Those skilled in the art should readily understand that various components, such as transistor components, bit line components, and/or capacitor components may be further disposed in the semiconductor structure 10 of this embodiment, in the cell region 100A, according to the actual device requirements, so as to form a dynamic random access memory device and to achieve better performance. For example, referring to FIG. 2, a capacitor component CAP may be disposed on the pad array 110 in the cell region 100A. According to one embodiment, the capacitor component CAP includes a plurality of bottom electrodes 413 vertically erected on the pad array 110, capacitive dielectric layers 411 overlying the surfaces of the bottom electrodes 413, top electrodes 415 disposed on the capacitive dielectric layers 411 and capacitively coupled to the bottom electrodes 413 through the capacitive dielectric layers 411, and at least one support layer 417 laterally extending between the bottom electrodes 413 of the capacitor component CAP. The support layer 417 may be in direct contact with and support each of the bottom electrodes 413.

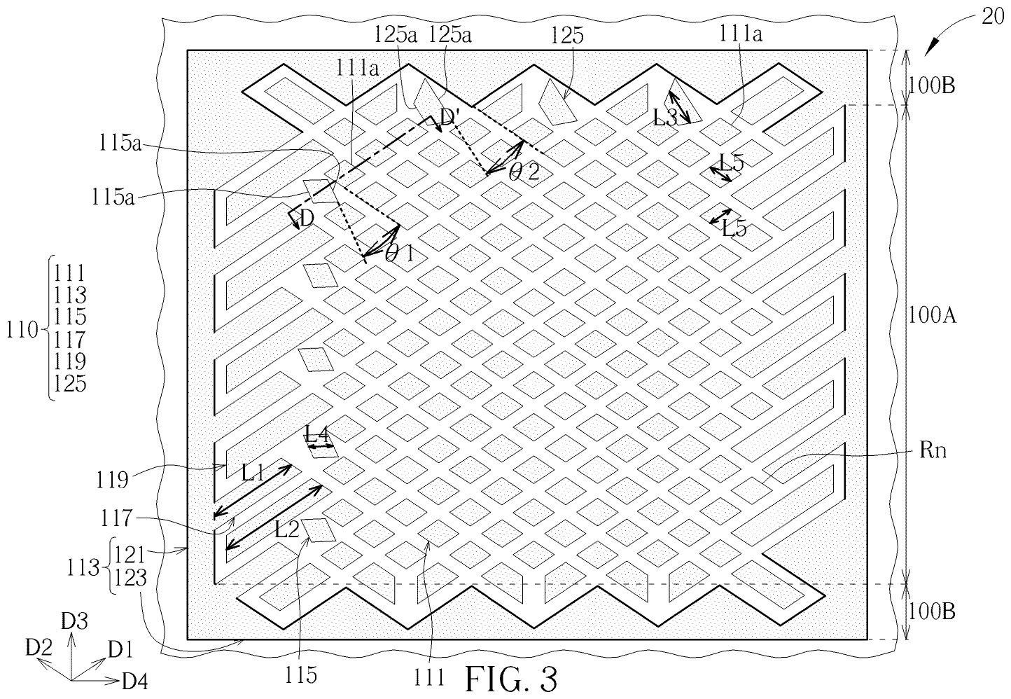

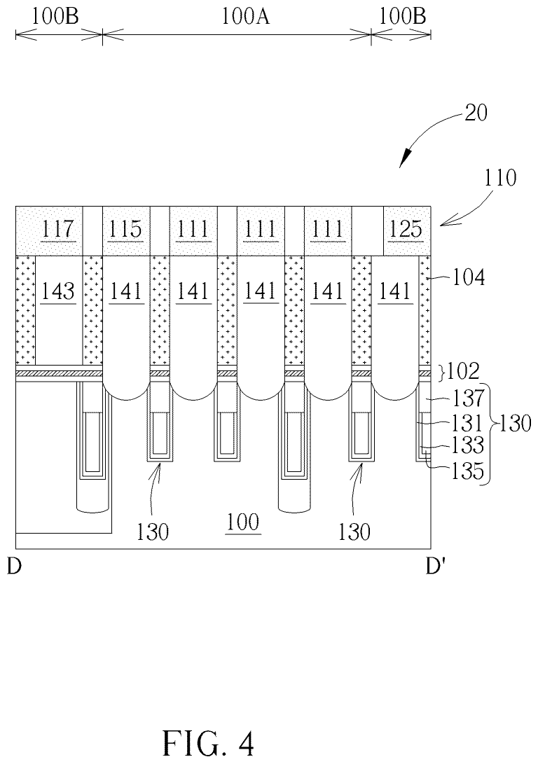

Refer to FIGS. 3 and 4, which are schematic diagrams of the semiconductor structure 20 in the second embodiment of the present invention. The semiconductor structure 20 of this embodiment is substantially the same as the semiconductor structure 10 of the previous embodiment, for example both include the pad array 110, the word lines 130, and the plug array 140, and the pad array 110 also includes the pads 111, the pad boundary 113, the first branches 117, and the second branches 119, with all the similarities therebetween being not redundantly described hereinafter.

As shown in FIGS. 3 and 4, the main difference between the semiconductor structure 20 of this embodiment and the semiconductor structure 10 of the first embodiment is that the pad array 110 further includes at least one peripheral pad 115/125 located either between one of the first edges 121 of the pad boundary 113 and a corresponding one of the pads 111, or between the second edge 123 of the pad boundary 113 and a corresponding one of the pads 111. The at least one peripheral pad 115/125 has two opposite lateral sides 115a/125a parallel to each other, while each pad 111 has two opposite lateral sides 111a parallel to the first direction D1 or the second direction D2. Moreover, the two opposite lateral sides 115a/125a of the at least one peripheral pad 115/125 are not parallel to the two opposite lateral sides 111a of any one of the pads 111 along the second direction D2. Under this configuration, as shown in FIG. 4, the at least one peripheral pad 115/125 can correspond to a corresponding one of the plugs 141 underneath, ensuring the contact area between the at least one peripheral pad 115/125 and the corresponding plug 141. Therefore, by disposing at least one peripheral pad 115/125 with the lateral sides not parallel to the lateral side 111a of the adjacent pad 111 disposed at the periphery of the pad array 110, for example, on at least one side of the pad array 110, the structural defects that may arise due to the continuously increasing cell density in the semiconductor structure 20 can be mitigated.

Specifically, as shown in FIG. 3, the semiconductor structure 20 includes a plurality of peripheral pads 115 and/or a plurality of peripheral pads 125. The peripheral pads 115 are respectively disposed between each of the first branches 117 and a corresponding one of the pads 111. The two opposite lateral sides 115a of each peripheral pad 115 are not parallel to the two opposite lateral sides 111a of the corresponding pad 111 in the second direction D2, wherein an angle θ1 between the two opposite lateral sides 115a of the peripheral pad 115 and the two opposite lateral sides 111a of the pad 111 is not greater than 90 degrees, but is not limited thereto. On the other hand, the peripheral pads 125 are disposed between one of the second edges 123 and a corresponding one of the pads 111 in the third direction D3. The two opposite lateral sides 125a of each peripheral pad 125 are also not parallel to the two opposite lateral sides 111a of the corresponding pad 111 in the second direction D2, and an angle θ2 between the two opposite lateral sides 125a of the peripheral pad 125 and the two opposite lateral sides 111a of the pad 111 is not greater than 90 degrees. The angle θ2 is preferably different from the angle θ1, but is not limited thereto. In one embodiment, each of the peripheral pads 115 and each of the peripheral pads 125 have different maximum extension lengths, for example. The maximum extension length L3 of each peripheral pad 125 is preferably greater than the maximum extension length L4 of each peripheral pad 115, or is greater than the length L5 of each pad 111 along the first direction D1 or the second direction D2. Furthermore, the maximum extension length L4 of the peripheral pad 115 is also preferably greater than the length L5 of each pad 111, but is not limited thereto.

According to the semiconductor structure 20 of the second embodiment of the invention, by disposing the peripheral pads 115/125 at the periphery of the pad array 110, for example on at least one side of the pad array 110, with each peripheral pad 115/125 having the lateral sides not parallel to the lateral side 111a of each pad 111 and/or having the maximum extension length greater than the length L5 of each pad 111, the peripheral pads 115/125 disposed adjacent to the pad boundary 113 can be able to correspond to the plugs 141 underneath, ensuring the contact area between the peripheral pads 115/125 and the corresponding plugs 141. Therefore, by disposing the peripheral pads 115/125 on at least one side of the pad array 110, the structural defects that may arise due to the continuously increased cell density in the semiconductor structure 20 can be mitigated, and the dynamic random access memory device, which can be further obtained thereby to achieve improved device performance.

To enable those skilled in the art to easily understand the semiconductor structure 10/20 of the present invention, the forming method of the semiconductor structure 10/20 of the present invention will be further described below.

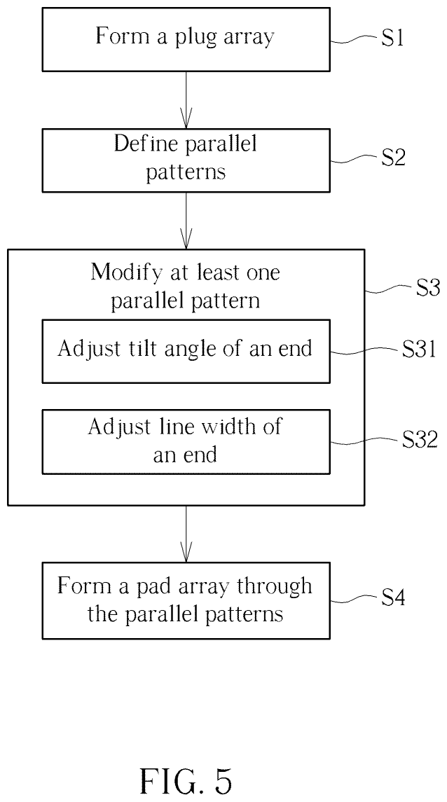

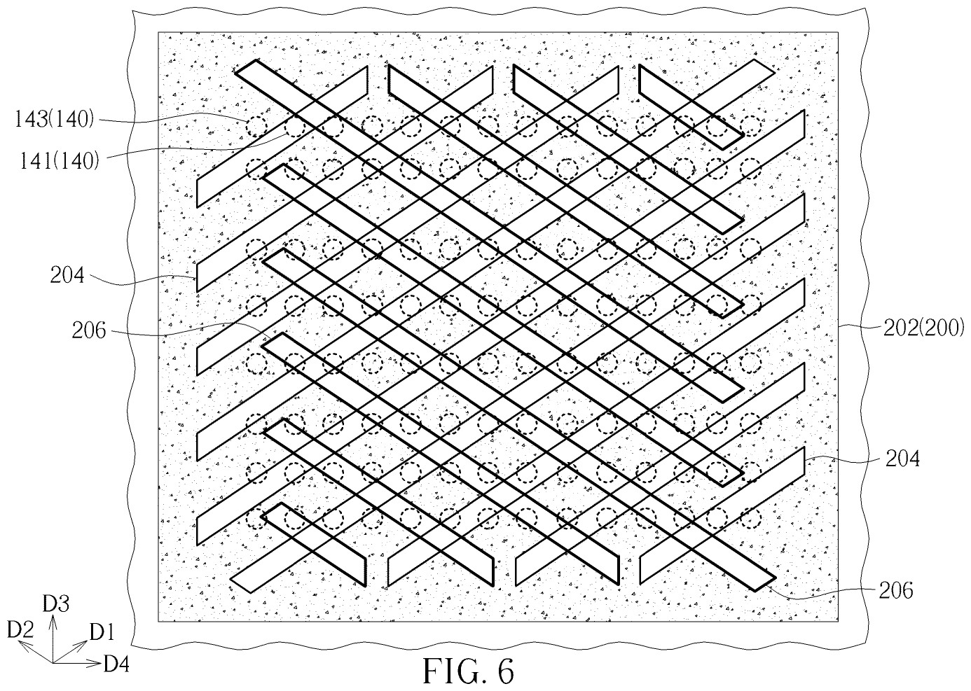

Refer to FIGS. 5 to 10, which are schematic diagrams of the forming method of the semiconductor structure 10/20 in a preferred embodiment of the present invention, where FIG. 5 is a schematic flow chart of the forming method of the semiconductor structure 10/20, and FIGS. 6 to 10 are schematic diagrams illustrating various forming processes of the semiconductor structure 10/20. First, refer to FIGS. 5 and 6, a chip 200 is provided, and the plug array 140 including the plugs 141 is formed on the chip 200 (step S1).

Next, a mask layer 202 is formed on the chip 200 to cover the plug array 110, and parallel patterns are defined on the mask layer 202 (step S2), the parallel patterns include a plurality of first parallel patterns 204 spaced apart along the first direction D1, and a plurality of second parallel patterns 206 spaced apart along the second direction D2. Each of the first parallel patterns 204 and each of the second parallel patterns 206 are, for example, in a strip shape respectively, and the first parallel patterns 204 and the second parallel patterns 206 are intersected to each other, as shown in FIG. 6.

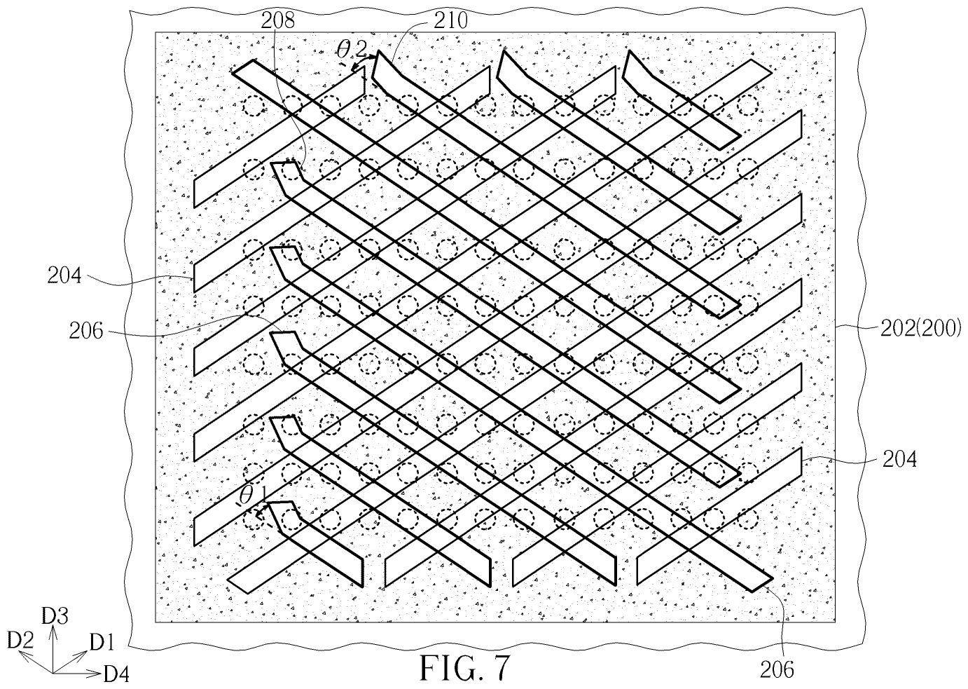

As shown in FIGS. 5 and 7, a modification step is performed to modify at least one parallel pattern (step S3), thereby defining at least one modified pattern 208/210. Specifically, according to the modification step, a tilt angle of an end of at least one second parallel pattern 206 (step S31) may be adjusted, with one end of at least one modified pattern 208/210 being deviated from the second direction D2 in a deviation angle θ1/θ2 for example, being less than 90 degrees, but is not limited thereto. Those skilled in the art may easily understand that in one embodiment, the modification step can be performed either on one end of any one of the second parallel patterns 206 or on one end of each of the second parallel patterns, according to actual manufacturing requirements. For example, before defining at least one modified pattern 208/210, a comparison step can be performed in advance, where an overlapping ratio between each second parallel pattern 206 and one corresponding plug underneath 141 is determined and compared with each other, for selecting the second parallel patterns 206 that need to be modified. The modification step is then performed on the selected second parallel pattern 206, so that the overlapping ratio between the at least one modified pattern 208/210 and the corresponding plug 141 underneath is greater than the overlapping ratio between the selected second parallel pattern 206 and the corresponding plug 141 underneath. Alternately, in another embodiment, the modification step may be performed on ends of a portion of the second parallel patterns 206, with each of the ends being deviated from the second direction D2 in a deviation angle θ1, while the modification step is also performed on ends of another portion of the second parallel patterns 206, with each of the ends being deviated from the second direction D2 in a deviation angle θ2, as shown in FIG. 7, but not limited thereto. The deviation angle θ2 is preferably not equal to the deviation angle θ1, so that the overlapping ratios between the modified patterns 208, 210 and the corresponding plugs 141 underneath can be greater than the overlapping ratio between the second parallel pattern 206 without undergoing the modification step and the corresponding plug 141.

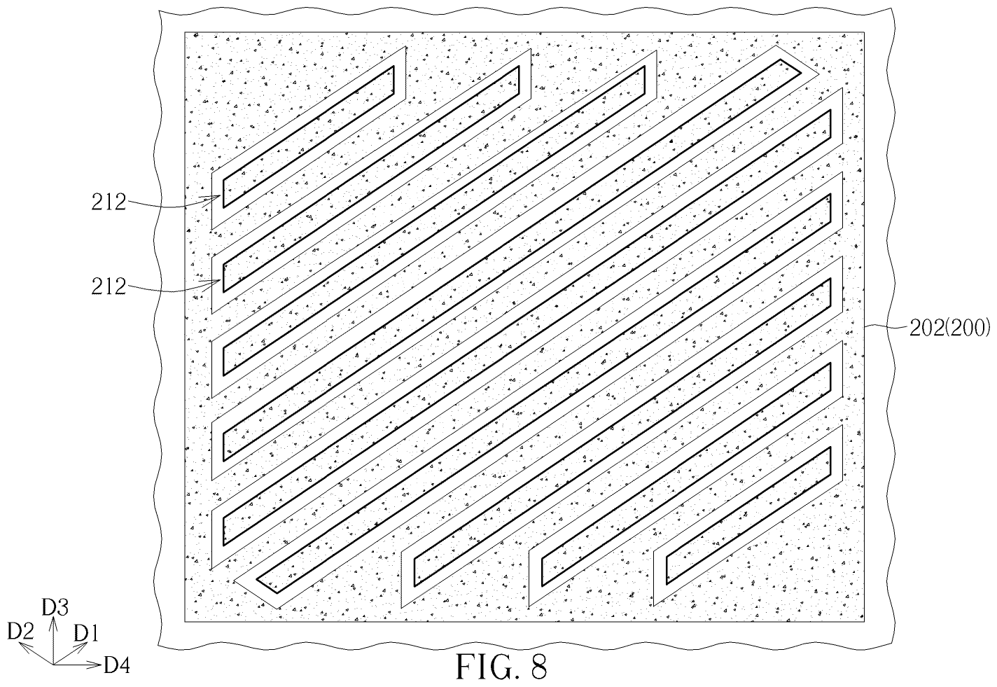

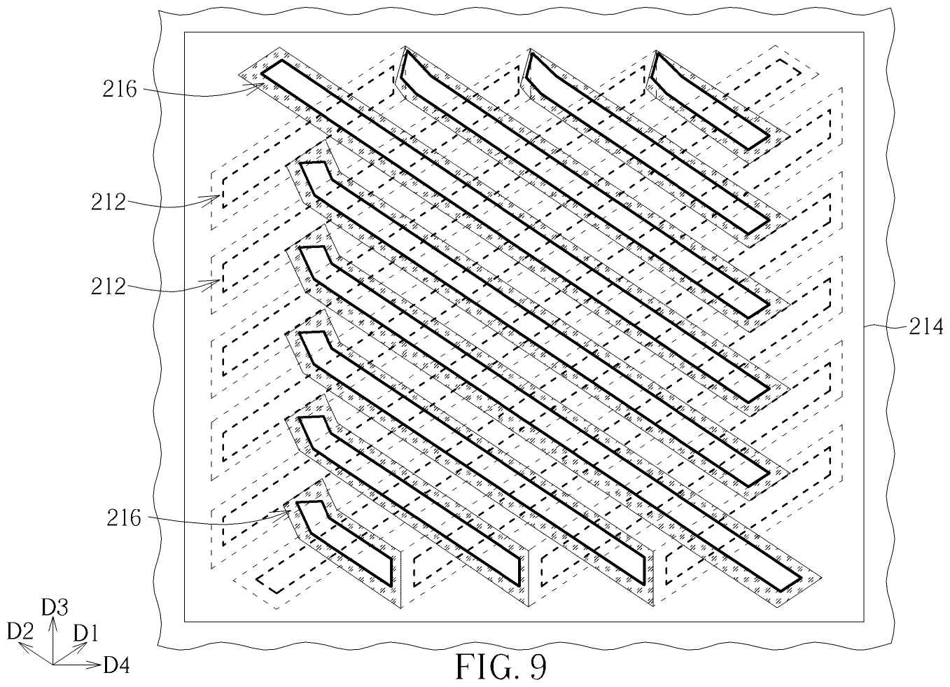

Afterward, as shown in FIGS. 5, 8 and 9, a pad array is formed through the parallel patterns (step S4) to form the semiconductor structure 10, 20 as shown in FIG. 1 or FIG. 3. Specifically, a first patterning process such as a first self-aligned reverse patterning (SARP) process is firstly performed through the first parallel patterns 204, to form a plurality of first openings 212 each in a rectangular frame shape, on the mask layer 202, as shown in FIG. 8. Next, a mask structure (not shown in the drawings) is formed on the mask layer 202 to cover all of the first openings 212. The mask structure for example has a multilayer structure including an organic bottom layer (not shown in the drawings), a silicon-based hard mask bottom anti-reflective coating 214, and a plurality of second mask patterns 216 each in a rectangular frame shape stacked in sequence, with each of the second mask patterns 216 being formed by performing a second patterning process such as a second self-aligned reverse patterning process, through the second parallel patterns 204 and the at least one modified pattern 208/210, as shown in FIG. 9. Then, a second etching process is performed through the second mask patterns 216 to sequentially transfer the rectangular frame pattern of the second mask patterns 216 into the silicon-based hard mask bottom anti-reflective coating 214 and the organic bottom layer below, followed by further transferring into the mask layer 202 underneath, to etch a plurality of second openings (not shown in the drawings) each in a rectangular frame shape on the mask layer 202. Subsequently, at least one etching process is performed to transfer the pattern on the mask layer 202 into a conductive material layer (not shown in the drawings) on the chip 200, so that the pad array 110 as shown in FIG. 1 or FIG. 3 can be formed on the conductive material layer, with the pad 110 including a plurality of the pads 111 and at least one peripheral pad 115/125, overlapping a corresponding plugs 141 underneath, respectively.

After these processes, the formation of the semiconductor structure 10/20 in the preferred embodiment of the present invention is completed. According to the forming method of this embodiment, the pads 111 in the pad array 110 are fabricated by performing two times of the self-aligned reverse patterning process, and the peripheral pads 115/125 are fabricated by performing the additional modification step. Thus, the overlapping ratio between one end of each second mask pattern 216 and the corresponding plug 141 underneath is allowable to be adjusted by performing the modification step, and accordingly, the gravity centers of the peripheral pads 115/125 formed thereby will be deviated from the gravity centers “A” of the adjacent pads 111, or the lateral sides of the peripheral pads 115/125 are not parallel to the lateral sides 111a of the adjacent pads 111, ensuring the overlapping ratio between the peripheral pads 115/125 and the corresponding plugs 141 underneath. Therefore, the possible structural defects that may arise from the continuously increased cell density in the semiconductor structure 10/20 can be mitigated through forming the peripheral pads 115/125 on at least one side of the pad array 110. Those skilled in the art can easily understand that various components such as a transistor component, a bit line component, and/or a capacitor component may be further formed within the cell region 100A of the semiconductor structure 10/20 in this embodiment, in order to meet the actual device requirements, such that, a dynamic random access memory device may be formed in the subsequent stage and achieves good device performance.

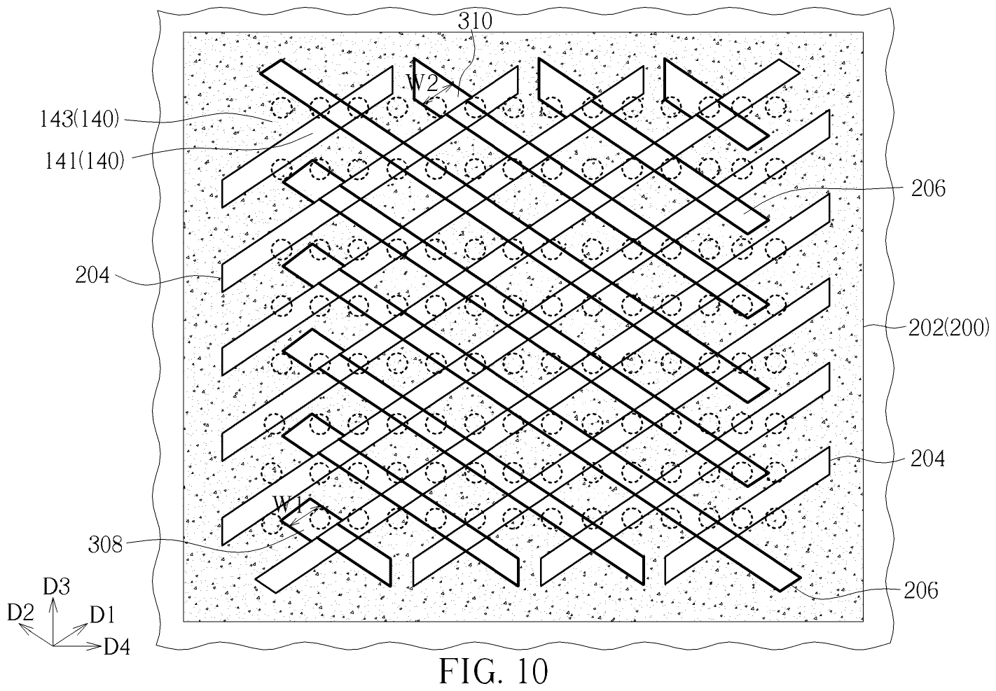

Furthermore, in order to meet actual product demands, the forming method of the semiconductor device of the present invention is not limited to those described above and may have other embodiments. For example, as shown in FIG. 10, in another embodiment, the modification step may also be performed by adjusting an end width of the at least one second parallel pattern 206, to form at least one modified pattern 308/310 with a relatively larger end width W1/W2. Accordingly, the overlapping ratio between the at least one modified pattern 308/310 and the corresponding plug 141 underneath is greater than the overlapping ratio between the at least one second parallel pattern 206 and the corresponding plug 141 underneath. Similarly, in order to meet the actual manufacturing requirements, the modification step of this embodiment can be performed either on one end of any one of the second parallel patterns 206, or on one end of each of the second parallel patterns 206. Alternately, the modification step of this embodiment may also be performed by adjusting end widths of a portion of the second parallel patterns 206 into a relatively larger end width W1, and adjusting end widths of the another portion of the second parallel patterns 206 into a relatively larger end line width W2, as shown in FIG. 10, but is not limited thereto. The end width W2 is preferably not equal to the end width W1, so that the overlapping ratio between the modified patterns 308, 310 and the corresponding plugs 141 underneath will be greater than the overlapping ratio between the second parallel pattern 206 and the corresponding plug 141 underneath. In other embodiments, the modification step may also be performed by simultaneously adjusting the inclined angle and the width of one end of at least one second parallel pattern 206, to further improve the overlapping ratio between the modified pattern (not shown in the drawings) and the corresponding plug 141 underneath. Therefore, through the aforementioned modification steps, the pads fabricated at the periphery of the pad array is allowable to obtain the peripheral pads 115/125 with gravity centers deviated from the gravity centers “A” of the adjacent pad 111, or with the lateral sides being not parallel to the sides 111a of the adjacent pads 111, thus ensuring the overlapping ratio between the peripheral pad 115/125 and the corresponding plug 141 underneath. In this way, the possible structural defects that may arise from the continuously increased cell density in the semiconductor structure will therefore be improved thereby.

Overall, according to the semiconductor structure and forming method thereof in the present invention, the modification step is performed before the two self-aligned reverse patterning processes, by adjusting the incline angle, and/or the width of one end of at least one pattern to ensure the coverage between the mask patterns formed accordingly and the corresponding plug underneath. Then, the peripheral pads formed according at the periphery of the pad array will therefore obtain the gravity centers deviated from the gravity centers of the adjacent pads, or the lateral sides being not parallel to the lateral sides of the adjacent pads, ensuring the overlapping ratio between the peripheral pads with and the corresponding plugs underneath. In this way, the structural defects that may arise from the continuously increased cell density in the semiconductor structure will be improved thereby. In this process, the forming method of the present invention can effectively avoid structural defects that may arise from the continuously increased cell density in the peripheral pads arranged at the periphery of the pad array, so that the semiconductor structure of the present invention can have a more optimized structure, a better component reliability, as well as an excellent operating performance and efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a pad array, comprising:
a plurality of pads spaced apart from each other along a first direction and a second direction, and disposed in a plurality of rows along the first direction;
a pad boundary disposed outside all of the pads and comprising a plurality of first branches extending along the first direction;
a plurality of second branches extending along the first direction and alternately disposed with the first branches along a third direction; and
at least one first peripheral pad, disposed between one of the first branches and one of the pads along the first direction, and between adjacent two of the second branches along the third direction, wherein a gravity center of the at least one first periphery pad is not on a same straight line with gravity centers the pads arranged in a same row with the at least one first periphery pad along the first direction.

2. The semiconductor structure according to claim 1, wherein the gravity center of the at least one first peripheral pad comprises a first distance and a second distance in the third direction related to two of the second branches adjacent to the at least one first peripheral pad, respectively, wherein the first distance is less than the second distance.

3. The semiconductor structure according to claim 1, wherein the gravity center of the at least one first peripheral pad comprises a third distance and a fourth distance in the first direction related to one of the pads and one of the first branches, respectively, wherein the third distance is less than the fourth distance.

4. The semiconductor structure according to claim 2, wherein the gravity center of each of the pads comprises a fifth distance and a sixth distance in the third direction related to adjacent two of the pads, respectively, wherein a difference between the fifth distance and the sixth distance is less than a difference between the first distance and the second distance.

5. The semiconductor structure according to claim 3, wherein the gravity center of each of the pads comprises a seventh distance and an eighth distance in the first direction related to adjacent two of the pads, respectively, wherein a difference between the seventh distance and the eighth distance is less than the difference between the third distance and the fourth distance.

6. The semiconductor structure according to claim 2, further comprising at least one second periphery pad disposed between the pad boundary and one of the pads along the third direction, wherein a gravity center of the at least one second peripheral pad comprises a ninth distance and a tenth distance in the third direction related to the pad boundary and the one of the pads, respectively, wherein the ninth distance is less than the tenth distance.

7. The semiconductor structure according to claim 6, wherein the at least one first peripheral pad and the at least one second peripheral pad are in different extension lengths.

8. The semiconductor structure according to claim 6, wherein the ninth distance is not equal to the first distance.

9. A semiconductor structure, comprising:
a pad array, comprising:
a plurality of pads disposed apart from each other along a first direction and a second direction, and the pads comprise two opposite lateral sides parallel to each other along the second direction;
a pad boundary disposed around all of the pads, the pad boundary comprising a plurality of branches extending along the first direction;
a plurality of second branches extending along the first direction and alternately disposed with the first branches along a third direction; and
at least one peripheral pad, disposed between the pad boundary and a corresponding one of the pads, wherein the at least one peripheral pad comprises two opposite lateral sides parallel to each other, and the two opposite lateral sides of the at least one peripheral pad are not parallel to the two opposite lateral sides of any of the pads.

10. The semiconductor structure according to claim 9, wherein an angle between one of the two opposite lateral sides of the at least one peripheral pad and one of the two opposite lateral sides of the pad is not greater than 90 degrees.

11. The semiconductor structure according to claim 9, wherein the at least one peripheral pad comprises a plurality of peripheral pads, and at least two of the peripheral pads comprise different maximum extension lengths.

12. The semiconductor structure according to claim 11, wherein each of the peripheral pads comprises an angle between the two opposite lateral sides of each of the peripheral pads and the two opposite lateral sides of each of the pads, and the two opposite lateral sides of at least two of the peripheral pads are in different angles with respect to the two opposite lateral sides of a corresponding one of the pads.

13. The semiconductor structure according to claim 9, wherein a maximum extension length of the at least one peripheral pad is greater than a length of each of the pads along the first direction.

14. The semiconductor structure according to claim 9, wherein the at least one peripheral pad is disposed between one of the first branches and one of the pads along the first direction, and is between adjacent two of the second branches along the third direction.

15. A method of forming a semiconductor structure, comprising:
providing a chip;
forming a plug array on the chip, the plug array comprising a plurality of plugs;
defining a plurality of first parallel patterns extending in a first direction on the chip;
defining a plurality of second parallel patterns extending in a second direction on the chip, wherein the second direction is different from the first direction;
modifying an end of at least one of the second parallel patterns to define at least one modified pattern, wherein an end of the at least one modified pattern deviates from the second direction; and
performing a first patterning process through the first parallel patterns, and performing a second patterning process through the at least one modified pattern and the second parallel patterns to form a pad array on the plugs, wherein the pad array comprises a plurality of pads and at least one peripheral pad overlapping the plugs respectively, the pad array further comprises a pad boundary disposed outside all of the pads, and a plurality of first branches extending along the first direction.

16. The method of forming a semiconductor structure according to claim 15, further comprising:
before defining the at least one modified pattern, selecting at least one of the second parallel patterns to be modified by comparing an overlapping ratio of each of the second parallel pattern and the each of the plugs, wherein an overlapping ratio of the end of the at least one modified pattern and a corresponding one of the plugs is greater than an overlapping ratio of the end of at least one of the second parallel pattern and the corresponding one of the plugs.

17. The method of forming a semiconductor structure according to claim 16, further comprising:
adjusting an end width of the at least one of the second parallel patterns to define the at least one modified pattern.

18. The method of forming a semiconductor structure according to claim 16, wherein the at least one modified pattern comprises a deviation angle with respect to the second direction, and the deviation angle is less than 90 degrees.

19. The method of forming a semiconductor structure according to claim 16, further comprising:
concurrently modifying ends of a plurality of the first parallel patterns to define a plurality of the modified patterns, wherein the modified patterns each comprises a deviation angle with respect to the second direction, and at least two of the modified patterns comprise different deviation angles.

20. The method of forming a semiconductor structure according to claim 16, further comprising:
concurrently modifying ends of a plurality of the first parallel patterns to define a plurality of the modified patterns, wherein at least two modified patterns comprise different end widths.
